(19) United States
(12) Patent Application Publication
(10) Pub. No.: US 2011/0303888 A1
(43) Pub. Date: Dec. 15, 2011

(54) NONVOLATILE MEMORY DEVICE

(75) Inventors: Hiroyuki FUKUMIZU, Mie-ken (JP); Yasuhiro Nojiri, Mie-ken (JP); Tsukasa Nakai, Tokyo (JP); Kazuhiko Yamamoto, Kanagawa-ken (JP)

(73) Assignee: Kabushiki Kaisha Toshiba, Tokyo (JP)

(21) Appl. No.: 13/044,865

(22) Filed: Mar. 10, 2011

(30) Foreign Application Priority Data
Jun. 15, 2010 (JP) 2010-136453

(51) Int. Cl. H01L 45/00

(52) U.S. Cl. 257/2; 257/537; 257/E45.002; 977/750; 977/752

(57) ABSTRACT

According to one embodiment, a nonvolatile memory device includes a memory cell connected to a first interconnect and a second interconnect. The memory cell includes a plurality of layers. The plurality of layers includes a carbon-containing memory layer sandwiched between a first electrode film and a second electrode film and a carbon-containing barrier layer provided at least one of between the first electrode film and the memory layer and between the second electrode film and the memory layer. The barrier layer has lower electrical resistivity than the memory layer.

### CROSS-REFERENCE TO RELATED APPLICATIONS

This application is based upon and claims the benefit of priority from the prior Japanese Patent Application No. 2010-136453, filed on Jun. 15, 2010; the entire contents of which are incorporated herein by reference.

### FIELD

Embodiments described herein relate generally to a nonvolatile memory device.

### BACKGROUND

Nonvolatile memories, such as NAND flash memories, are widely used for high capacity data storage in cellular phones, digital still cameras, USB (Universal Serial Bus) memories, silicon audio players and the like. Furthermore, novel applications have also been fast emerging, causing demand for miniaturization and manufacturing cost reduction thereof. In particular, in a NAND flash memory, a plurality of active areas (“A.A.”) share a gate conductor (“G.C.”). A NAND flash memory is based on the operation of a transistor which records information using its threshold variation. Thus, reportedly, the NAND flash memory has limitations on further improvement in characteristics uniformity, reliability, operating speed, and integration density.

In this context, for instance, the phase change memory element or resistance change memory element is based on the variable resistance state of a resistance material, and hence needs no transistor operation in program/erase operation.

However, in such elements, there is demand for further improvement in characteristics uniformity, reliability, operating speed, and integration density.

### BRIEF DESCRIPTION OF THE DRAWINGS

FIGS. 1A to 2C are schematic views of the main part of a memory cell section of a nonvolatile memory device according to a first embodiment;

FIGS. 3A to 3D illustrate the operation of the memory cell according to the first embodiment;

FIGS. 4A and 4B illustrate the operation of a memory cell of a comparative example;

FIGS. 5A to 7B illustrate a method for manufacturing the memory cell according to the first embodiment;

FIG. 8 is a schematic view of the main part of a memory cell section of a nonvolatile memory device according to a second embodiment;

FIGS. 9A and 9B illustrate Raman spectra of carbon films; and

FIGS. 10A to 10D illustrate the main part of the operation of the memory cell according to the second embodiment.

### DETAILED DESCRIPTION

In general, according to one embodiment, a nonvolatile memory device includes a memory cell connected to a first interconnect and a second interconnect. The memory cell includes a plurality of layers. The plurality of layers includes a carbon-containing memory layer sandwiched between a first electrode film and a second electrode film and a carbon-containing barrier layer provided at least one of between the first electrode film and the memory layer and between the second electrode film and the memory layer. The barrier layer has lower electrical resistivity than the memory layer.

### First Embodiment

Various embodiments will be described hereinafter with reference to the accompanying drawings.

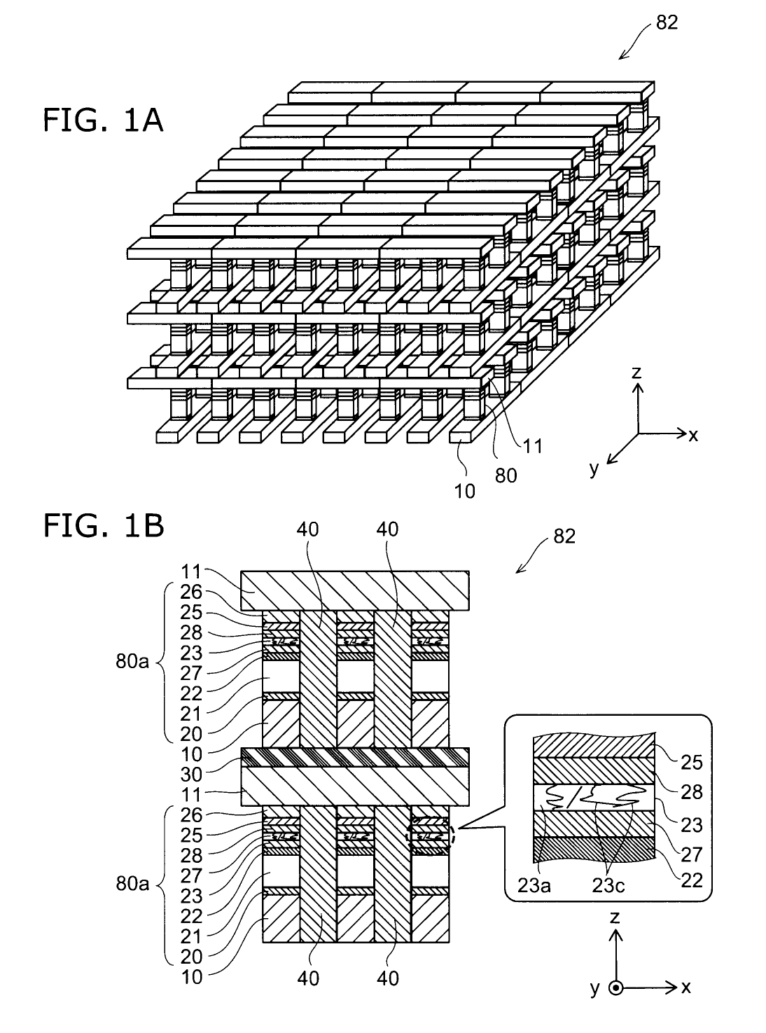

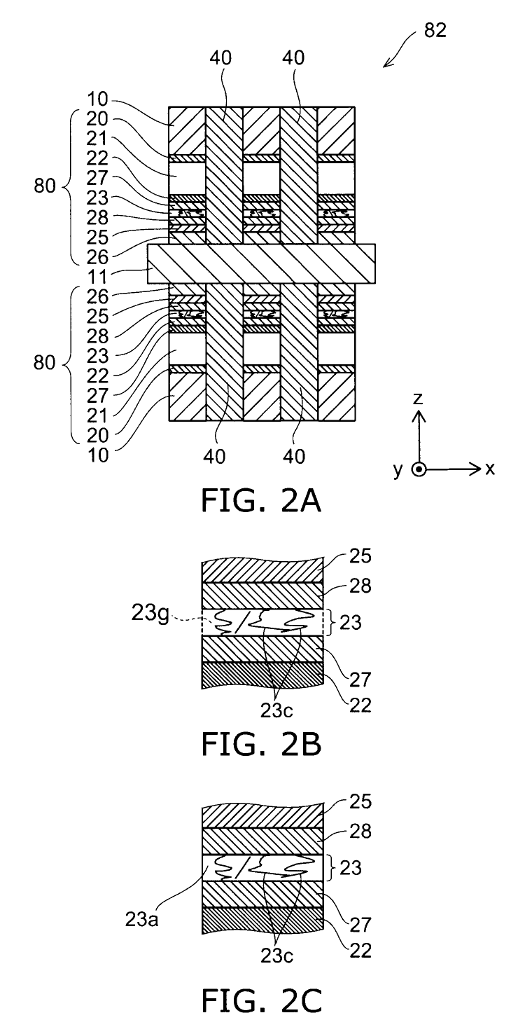

FIGS. 1A to 2C are schematic views of the main part of a memory cell section of a nonvolatile memory device according to a first embodiment.

First, the memory cell section of the nonvolatile memory device is described with reference to FIGS. 1A and 1B. FIG. 1A is a perspective view of the main part of the memory cell section. FIG. 1B shows a cross section of a memory cell (memory unit element) 80 provided at the crossing position of a lower interconnect (bit line) 10 and an upper interconnect (word line) 11 of FIG. 1A. The memory section 82 of the nonvolatile memory device has a cross-point ReRAM (resistance random access memory) cell array structure.

The memory section 82 of the nonvolatile memory device includes lower interconnects 10 as first interconnects, and upper interconnects 11 as second interconnects. The upper interconnects 11 extend in a first direction (X-axis direction in the figures). The upper interconnects 11 are periodically arranged in a second direction (Y-axis direction in the figures). The lower interconnects 10 extend in the second direction (Y-axis direction in the figures) non-parallel to the first direction. The lower interconnects 10 are periodically arranged in the first direction.

The memory cell 80 is sandwiched between the lower interconnect 10 and the upper interconnect 11. That is, the memory cell 80 lies between the lower interconnect 10 and the upper interconnect 11 crossing each other (lies at the cross-point position). The memory density can be increased by stacking the lower interconnects 10, the upper interconnects 11, and the memory cells 80 in the Z-axis direction in the figures.

As shown in FIG. 1B, the memory cell 80 includes a stacked body sequentially composed of, from bottom to top, a lower interconnect 10, a metal film 20, a diode layer 21, a metal film 22 as a first electrode film, a low resistance carbon film 27 as a barrier layer, a layer 23 containing a plurality of carbon nanotubes as a recording layer (hereinafter CNT-containing layer), a low resistance carbon film 28 as a barrier layer, and a metal film 25 as a second electrode film. The electrical resistivity of the low resistance carbon films 27, is set lower than the electrical resistivity of the CNT-containing layer 23. The thickness of the low resistance carbon film 27, 28 is e.g. 5 to 10 nm. The thickness of the CNT-containing layer 23 is e.g. 10 to 50 nm. The CNT-containing layer 23 functions as a memory layer. The memory layer based on the CNT-containing layer 23 achieves faster switching operation than the memory layer primarily composed of oxide film (e.g., manganese oxide). A stopper interconnect film 26 for CMP (chemical mechanical polishing) is provided on the metal film 25.

In each memory cell 80, its metal film 20 is electrically connected to the lower interconnect 10, and its stopper interconnect film 26 is electrically connected to the upper interconnect 11. In each memory cell 80, the diode layer 21 and the CNT-containing layer 23 are connected in series so that a current flows in one direction in the memory cell 80. Furthermore, in the memory section 82, an interlayer insulating film 30 is interposed between the upper interconnect 11 and the lower interconnect 10.

Thus, the memory section 82 has a structure in which the unit including the lower interconnect 10, the memory cell 80, and the upper interconnect 11 is stacked in a plurality of stages. An element isolation layer 40 is provided between the adjacent memory cells 80 to ensure insulation between the memory cells 80. The width of the memory cell 80 is 100 nm or less. In the embodiments, unless otherwise specified, the “width” of a portion refers to the diameter of the cross section of the portion cut generally perpendicular to the Z-axis direction.

A voltage is applied to the lower interconnect 10 and the upper interconnect 11 of such a memory section 82, and a desired current flows in the CNT-containing layer 23. Then, the CNT-containing layer 23 reversibly transitions between a first state and a second state. For instance, the voltage applied between the major surfaces of the CNT-containing layer 23 changes, and the resistance of the CNT-containing layer 23 reversibly changes between the first state and the second state. This makes it possible to store digital information (such as “0” or “1”) in the memory cell 80, and to erase digital information from the memory cell 80. Here, programming from “0” to “1” is referred to as “set operation”, and programming from “1” to “0” is referred to as “reset operation”. For instance, the high resistance state of the CNT-containing layer 23 is associated with “0”, and the low resistance state of the CNT-containing layer 23 is associated with “1”.

Besides the ReRAM cell array structure shown in FIG. 1A, the memory section 82 may have a structure shown in FIG. 2A.

In the ReRAM memory cell array shown in FIG. 2A, the upper interconnect 11 as a word line is provided not for each stage, but is shared by the memory cells 80 placed above and below this upper interconnect 11.

For instance, with respect to the upper interconnect 11 in the figure taken as the axis of symmetry, the memory cell 80 below the upper interconnect 11 and the memory cell 80 above the upper interconnect 11 are placed axisymmetrically.

In addition to increasing the memory density, by the sharing of the upper interconnect 11, such a structure can suppress the delay of voltage application to the upper interconnect 11, accelerate the program operation and erase operation, and reduce the element area, for instance.

Thus, the nonvolatile memory device of the first embodiment includes upper interconnects 11 extending in the X-axis direction, lower interconnects 10 extending in the Y-axis direction non-parallel to the X-axis direction, and memory cells 80 each provided at the crossing position of the upper interconnect 11 and the lower interconnect 10. However, the first embodiment is not limited to this example. For instance, this embodiment also encompasses a nonvolatile memory device in which the unit including the lower interconnect 10, the memory cell 80, and the upper interconnect 11 is not stacked in a plurality of stages.

The memory cell 80 is described in more detail. The CNT-containing layer 23 has a structure shown in FIG. 2B or 2C.

The CNT-containing layer 23 shown in FIG. 2B includes a plurality of CNTs 23c in the gap 23g between the low resistance carbon film 27 and the low resistance carbon film 28. The gap 23g is hollow.

The CNT-containing layer 23 shown in FIG. 2C includes an insulating material 23a around the CNTs 23c. That is, an insulating material 23a dispersed with a plurality of CNTs 23c is provided between the low resistance carbon film 27 and the low resistance carbon film 28.

In this embodiment, the plurality of CNTs 23c and the gap 23g are collectively referred to as the CNT-containing layer 23. Alternatively, the plurality of CNTs 23c and the insulating material 23a are collectively referred to as the CNT-containing layer 23. In these CNT-containing layers 23, one end of at least one carbon nanotube 23c of the plurality of carbon nanotubes 23c is in contact with the low resistance carbon film 27, and one other end is in contact with the low resistance carbon film 28.

The CNT 23c may be a single-wall nanotube (SWNT) made of a single layer, or a multi-wall nanotube (MWNT) made of multiple layers. For SWNTs, the diameter of the CNT 23c is approximately 2 nm.

The low resistance carbon film 27, 28 is made of e.g. amorphous carbon. The low resistance carbon film 27, 28 is formed by plasma CVD (chemical vapor deposition) (described later).

The insulating material 23a is an oxide material such as silicon oxide (SiO₂), alumina (Al₂O₃), silicon oxycarbide (SiOC), and magnesium oxide (MgO), or an organic insulator such as resist. The insulating material 23a may be a high-k material or low-k material. At least part of the insulating material 23a may be fine-grained.

The material of the lower interconnect 10, the upper interconnect 11, and the stopper interconnect film 26 is e.g. tungsten (W), which is superior in high-temperature heat resistance and has low electrical resistivity. Alternatively, the stopper interconnect film 26 may be made of a material such as tungsten nitride (WN), tungsten carbide (WC), titanium (Ti), and titanium nitride (TiN).

The metal film 20, 22, 25 is made of a material such as titanium (Ti), titanium nitride (TiN), tungsten (W), tungsten nitride (WN), and platinum (Pt).

The diode layer 21 is e.g. a rectifying element primarily composed of polysilicon (poly-Si), such as a PIN diode, PN junction diode, Schottky diode, and Zener diode. Besides silicon, the material of the diode layer 21 may be a combination of semiconductor materials such as germanium (Ge), and metal oxide semiconductor materials such as NiO, TiO, CuO, and InZnO.

To ensure stable ohmic contact between the metal film 20, 22 and the diode layer 21, a layer made of components different from those of the metal film 20, 22 may be provided at the interface between the metal film 20, 22 and the diode layer 21. This layer is e.g. a metal silicide film. The metal silicide film is formed by annealing the metal film 20, 22 and the diode layer 21.

The element isolation layer 40 is made of a material such as silicon oxide (SiO₂), FSG (SiOF), BSG (SiO₂—B₂O₃, SiOB), HSQ (Si—H-containing SiO₂), porous silica, carbon-containing porous silica, carbon-containing SiO₂ (SiOC), silicon nitride (Si₃N₄), aluminum nitride (AlN), alumina (Al₂O₃), silicon oxynitride (SiON), hafnia (HfO₂), MSQ (methyl group-containing SiO₂), porous MSQ, polyimide-based polymer resin, parylene-based polymer resin, and Teflon®-based polymer resin.

The element isolation layer 40 may be configured so that its density is higher than that of the insulating material 23a. For instance, the element isolation layer 40 including silicon (Si) may be formed by CVD using high density plasma so that its density is made higher than that of the insulating material 23a. Alternatively, in the case of forming the element isolation layer 40 by the coating method, the element isolation layer 40 may be baked so that its density is made higher than that of the insulating material 23a.

Next, an example operation of the memory cell 80 is described. The memory cell 80 shown in FIG. 2B is taken as an example.

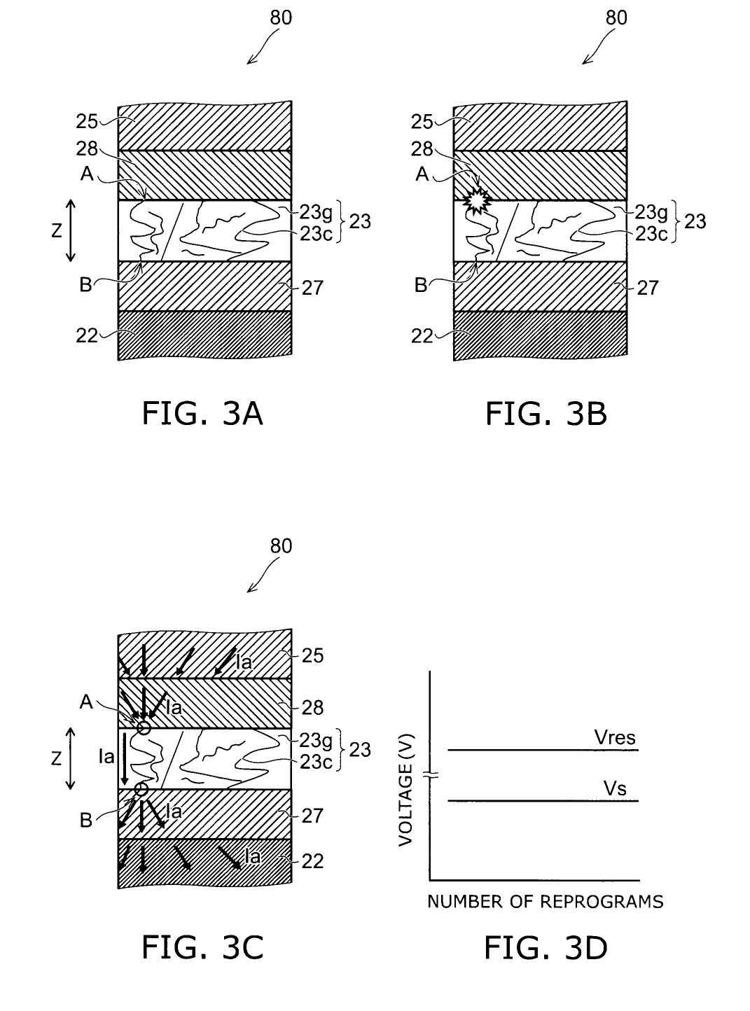

FIGS. 3A to 3D illustrate the operation of the memory cell according to the first embodiment.

In the initial state shown in FIG. 3A, one end of at least one carbon nanotube 23c of the plurality of carbon nanotubes 23c is in contact with the low resistance carbon film 28, and the one other end is in contact with the low resistance carbon film 27. The contact sites are referred to as site A and site B, respectively.

When both ends of the CNT 23c are in contact with the low resistance carbon films 27, 28, the resistance between the low resistance carbon film 27 and the low resistance carbon film 28 is determined by the resistance of this CNT 23c being in contact therewith. The resistance in this state is referred to as first resistance.

First, the reset operation of the memory cell 80 is performed. Before the reset operation, one end of the CNT 23c is in contact with the low resistance carbon film 27 at the site B, and the one other end of the CNT 23c is in contact with the low resistance carbon film 28 at the site A. Hence, if a first voltage is applied between the low resistance carbon film 27 and the low resistance carbon film 28 by the reset operation, a current flows preferentially in the CNT 23c running (linking) between the site A and the site B. In this case, the current flows through the CNT 23c having a nanoscale diameter. Hence, the current flowing in the CNT 23c has high current density.

In this state, passage of the current is continued for a prescribed time (longer than in the set operation). Then, the CNT 23c is broken by heat generation in the CNT 23c due to the passage of current. This state is shown in FIG. 3B. FIG. 3B shows the state of the CNT 23c broken near the site A, for instance. By this breakage, the resistance between the low resistance carbon film 27 and the low resistance carbon film 28 sharply increases. The resistance in this state is referred to as second resistance. That is, the resistance between the low resistance carbon film 27 and the low resistance carbon film 28 changes from the low resistance state to the high resistance state.

Subsequently, the set operation is performed on the memory cell 80. Then, the low resistance carbon film 28 and the low resistance carbon film 27 are electrically reconnected. Possible reasons for this are as follows.

(1) The CNT 23c, once broken, extends again to the low resistance carbon film 28 and is brought into contact with the low resistance carbon film 28.

(2) The CNTs 23c separated from each other by breakage are again brought into contact with each other by the van der Waals force.

(3) Besides the broken CNT 23c, another CNT 23c connects between the low resistance carbon film 27 and the low resistance carbon film 28.

Thus, the resistance between the low resistance carbon film 27 and the low resistance carbon film 28 changes from the high resistance state to the low resistance state.

Other reasons for transition of the CNT 23c between the low resistance state and the high resistance state are as follows.

(4) Passage of current in the CNT 23c causes the bonding state of the CNT 23c to reversibly transition between a first state and a second state. (The first state is e.g. the sp² state of carbon-carbon bonding, and the second state is e.g. the sp³ state.)

(5) In the set and reset operation, redox reactions occur at the interface between the CNT-containing layer 23 and the low resistance carbon film 27, 28.

In the set operation, the voltage is applied for a shorter time than the aforementioned prescribed time. Hence, the CNT 23c is less likely to break than in the reset operation. That is, breakage of the CNT 23c can occur preferentially in the reset operation. With the first state associated with information “0” and the second state associated with information “1”, information of “0” and “1” is repeatedly written and erased in the memory cell 80.

In the actual memory cell 80, the CNTs 23c are entangled with each other. Hence, the current path between the low resistance carbon film 27 and the low resistance carbon film 28 is not necessarily constituted by one CNT 23c linking between the low resistance carbon film 27 and the low resistance carbon film 28. For instance, the current path may start with a first CNT 23c in contact with the low resistance carbon film 28 at the site A and switch to a second CNT 23c in contact with the first CNT 23c, and the second CNT 23c may be in contact with the low resistance carbon film 27. However, such a case is no different in that the CNT 23c is in contact with the low resistance carbon film 28 at a pinpoint site A on the low resistance carbon film 28 side. Hence, the CNT 23c can break near the site A by the reset operation. This enables the aforementioned operation.

Thus, in the memory cell 80, the CNT 23c reversibly changes between the first state and the second state. The CNT-containing layer 23 itself including such CNTs 23c contributes to memory switching (programming and erasure of information).

In the memory cell 80, as shown in FIG. 3C, a high density current Ia concentrates on the CNT 23c and flows through the CNT 23c. Hence, the current Ia concentrates on the sites A, B. This may locally generate heat near the sites A, B. However, the CNT 23c and the low resistance carbon film 27, 28 are both primarily composed of carbon. Hence, local heat generation is less likely to cause interdiffusion of components between the low resistance carbon film 27, 28 and the CNT 23c. Likewise, chemical reaction is less likely to occur between the low resistance carbon film 27, 28 and the CNT 23c.

Furthermore, in the memory cell 80, the current Ia diffuses in the low resistance carbon film 27, 28 having low electrical resistivity, and then further diffuses in the metal film 22, 25 having lower electrical resistivity than the low resistance carbon film 27, 28. Hence, concentration of the current Ia is less likely to occur at the interface of the metal film 22 and the low resistance carbon film 27, and the interface of the metal film 25 and the low resistance carbon film 28. Thus, interdiffusion of components and chemical reaction are less likely to occur at the interface of the metal film 22 and the low resistance carbon film 27, and the interface of the metal film 25 and the low resistance carbon film 28. In other words, the low resistance carbon film 27, 28 functions as a barrier layer provided between the CNT-containing layer 23 and the metal film 22, 25.

Hence, denoting the set voltage by Vs and the reset voltage by Vres, Vs and Vres are stably maintained as shown in FIG. 3D even if the number of reprograms (or the number of switching times) increases.

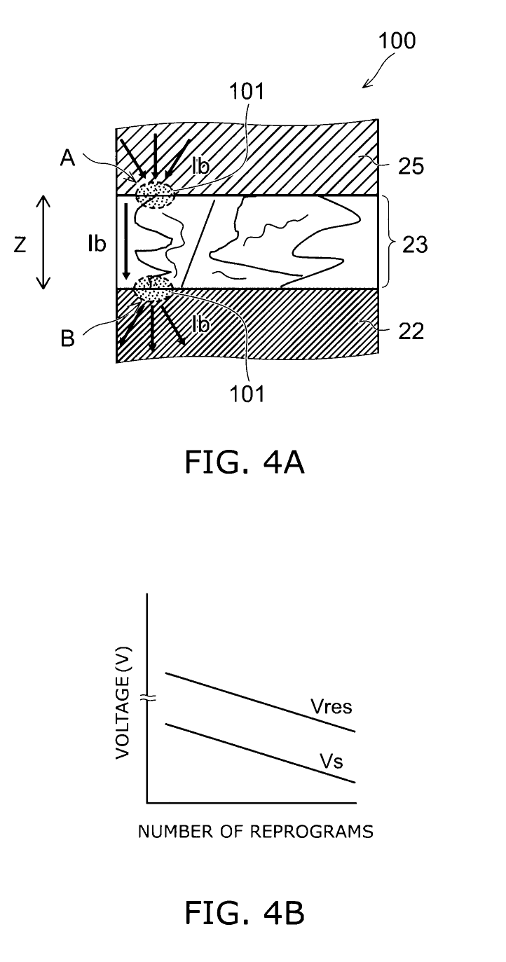

In contrast, FIGS. 4A and 4B illustrate the operation of a memory cell 100 of a comparative example.

As shown in FIG. 4A, the memory cell 100 of the comparative example does not include the low resistance carbon film 27, 28. Hence, the metal film 22, 25 is in direct contact with the CNT-containing layer 23. Here, if the aforementioned program/erase operation is repeated, a high density current Ib flows through the CNT 23c. Hence, the current Ib concentrates on the sites A, B. This locally generates heat at the sites A, B.

The memory cell 100 does not include the low resistance carbon film 27, 28. By that amount, the length between the metal film 22 and the metal film 25 of the memory cell 100 is shorter than the length between the metal film 22 and the metal film 25 of the memory cell 80. Thus, the resistance between the metal film 22 and the metal film 25 of the memory cell 100 is lower than the resistance between the metal film 22 and the metal film 25 of the memory cell 80. Hence, if the voltage applied between the metal film 22 and the metal film 25 of the memory cell 100 is equal to the voltage applied between the metal film 22 and the metal film 25 of the memory cell 80, the current Ib is higher than the current Ia. This further increases the local heat generation, and makes interdiffusion of components and chemical reaction more likely to occur between the metal film 22, 25 and the CNT 23c.

Hence, with the increase of the number of reprograms on the memory cell 100, a carbide layer 101, for instance, occurs at the interface of the metal film 22, 25 and the CNT-containing layer 23. The carbide layer 101 is made of e.g. a metal carbide such as titanium carbide (TiC), titanium carbonitride (TiCN), tungsten carbide (WC), and tungsten carbonitride (WCN). The carbide layer 101 grows with the increase of the number of reprograms. This carbide layer 101 may penetrate into the CNT-containing layer 23 with the increase of the number of reprograms. Thus, the length of the CNT 23c may shorten with the increase of the number of reprograms. Furthermore, if the metal component of the metal film 22, 25 diffuses into the CNT-containing layer 23, the conductivity of the CNT-containing layer 23 itself may increase.

Hence, in the memory cell 100, denoting the set voltage by Vs and the reset voltage by Vres, Vs and Vres decrease with the increase of the number of reprograms. This behavior is shown in FIG. 4B. That is, in the memory cell 100, Vs and Vres are less stable than in the memory cell 80.

In the comparative example, Vs and Vres decrease with the increase of the number of reprograms and asymptotically approach 0 V. Then, the difference between Vs and Vres is reduced. Thus, the discrimination between Vs and Vres is made difficult, and malfunctions are made more likely to occur in the program operation and the read operation. To avoid this, the CNT-containing layer 23 may be formed with a larger thickness (layer thickness) so that a certain thickness remains even after the thickness erosion of the CNT-containing layer 23. However, with the increase of the thickness of the CNT-containing layer 23 formed, the aspect ratio of the memory cell 100 increases. This decreases the mechanical strength of the memory cell.

In contrast, in the memory cell 80 according to the first embodiment, the lower interconnect 10 and the upper interconnect 11 are electrically connected. The memory cell 80 includes a plurality of layers. More specifically, the memory cell 80 includes, as a memory layer, a CNT-containing layer 23 containing carbon, and low resistance carbon films 27, 28 connected to the CNT-containing layer 23. The low resistance carbon film 27, 28 functions as a barrier layer. The low resistance carbon film 27, 28 has lower electrical resistivity than the CNT-containing layer 23. The density of unsaturated bonds included in the low resistance carbon film 27, 28 serving as a barrier layer is higher than the density of unsaturated bonds included in the CNT-containing layer 23.

In such a structure, the barrier function of the low resistance carbon films 27, 28 makes the CNT-containing layer 23 less prone to erosion. Furthermore, the barrier function of the low resistance carbon films 27, 28 makes the metal component of the metal film 22, 25 less likely to diffuse into the CNT-containing layer 23. Thus, the memory cell 80 has higher reliability than the comparative example.

Furthermore, because the barrier function of the low resistance carbon films 27, 28 makes the CNT-containing layer less prone to erosion, there is no need to form the CNT-containing layer 23 with a large thickness as in the comparative example. This suppresses the increase of aspect ratio of the memory cell 80, and increases the mechanical strength of the memory cell 80.

In the first embodiment, the configuration including the low resistance carbon films 27, 28 has been illustrated. However, one of the low resistance carbon films 27, 28 may be omitted as necessary.

Next, a method for manufacturing the memory cell 80 is described.

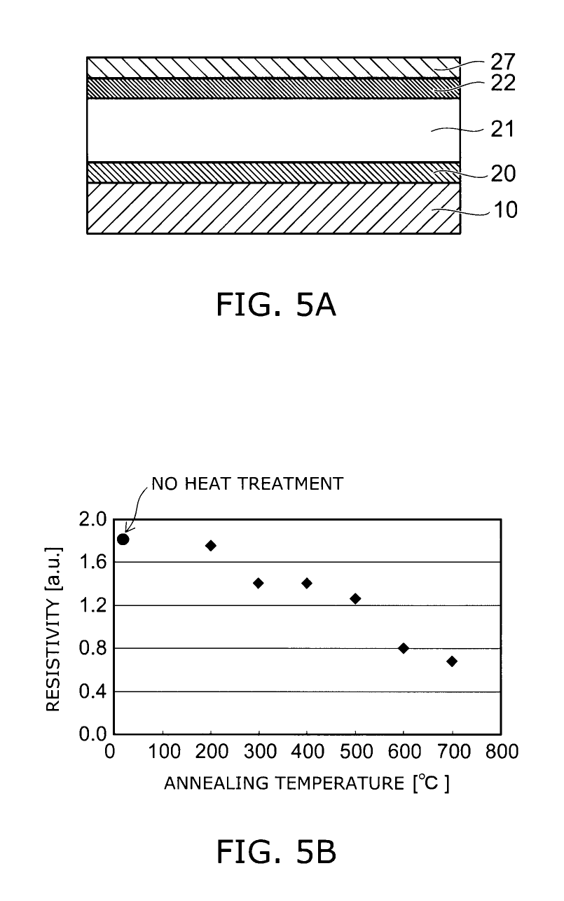

FIGS. 5A to 7B illustrate the method for manufacturing the memory cell according to the first embodiment.

First, a stacked body having the same layer configuration as the memory cell 80 is formed. For instance, as shown in FIG. 5A, on a lower interconnect 10, a stacked film is formed in the order of a metal film 20, a diode layer 21, and a metal film 22. The lower interconnect 10, the metal film 20, the diode layer 21, and the metal film 22 are formed by e.g. sputtering or CVD.

Subsequently, a low resistance carbon film 27 is formed on the metal film 22. The raw material gas used in the film formation of the low resistance carbon film 27 is e.g. C₃H₆ (propylene)/He gas. The film formation temperature is e.g. 550° C. In the film formation of the low resistance carbon film 27, sp² bonds in the low resistance carbon film increase with the increase of film formation temperature. Furthermore, the resistance of the low resistance carbon film 27 decreases with the increase of sp² bonds. Hence, in the film formation of the low resistance carbon film 27, the film formation temperature is not limited to 550° C., but suitably changed so as to achieve a desired electrical resistivity.

Furthermore, the low resistance carbon film 27 can be subjected to heat treatment (RTA (rapid thermal anneal) treatment) to adjust its electrical resistivity.

For instance, FIG. 5B shows the relationship between annealing temperature (° C.) and electrical resistivity (Ω·cm). The horizontal axis represents annealing temperature, and the vertical axis represents electrical resistivity in arbitrary unit (a.u.). The heat treatment is performed in a nitrogen (N₂) atmosphere for one minute. As shown, with the increase of annealing temperature, the electrical resistivity gradually decreases. Thus, the electrical resistivity of the low resistance carbon film 27 can be adjusted by the annealing temperature. Here, the electrical resistivity of the low resistance carbon film 27 decreases as the annealing time becomes longer. Hence, the electrical resistivity of the low resistance carbon film 27 can be adjusted also by the annealing time.

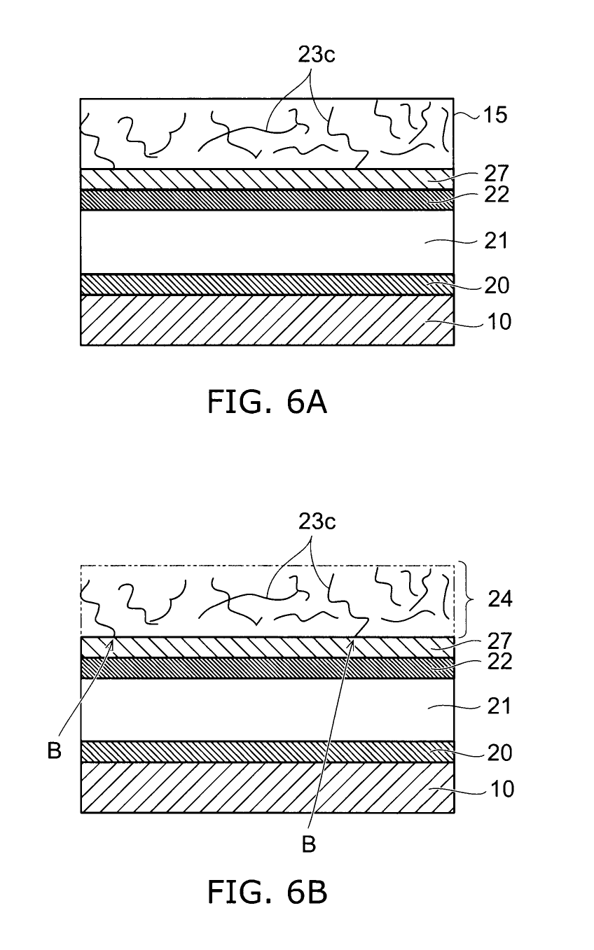

Next, as shown in FIG. 6A, a solution dispersed with CNTs 23c is applied onto the low resistance carbon film 27. The application is performed by spin coating. The solvent is water or an organic solvent (such as ethanol). Thus, a coating film 15 including CNTs 23c is formed on the low resistance carbon film 27.

Next, as shown in FIG. 6B, the coating film 15 is heated to evaporate (vaporize) the solvent. Thus, a layer 24 dispersed with a plurality of CNTs 23c is formed on the low resistance carbon film 27.

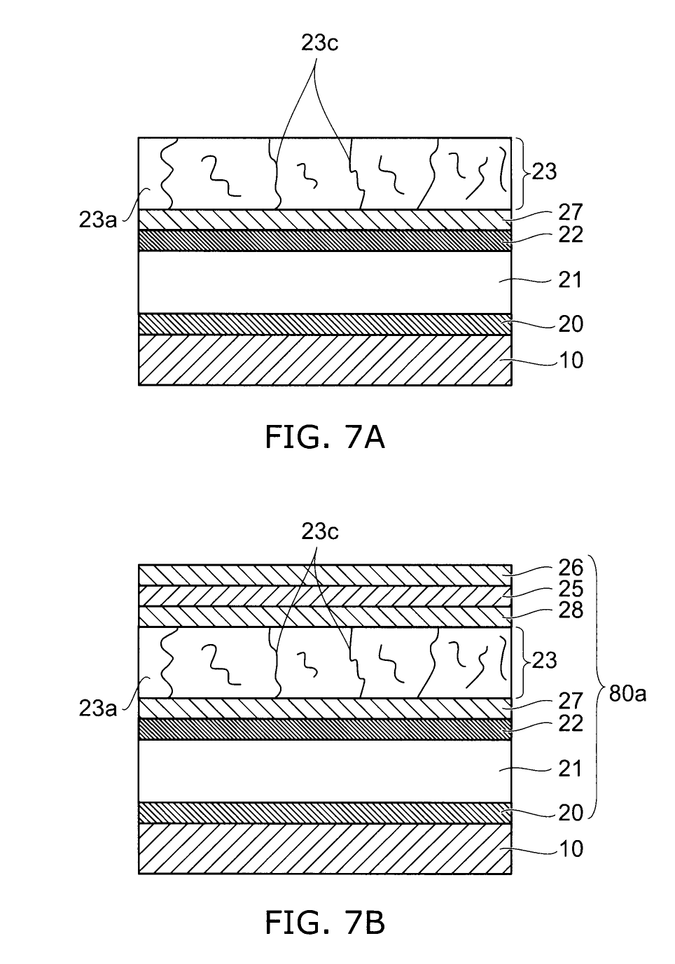

Next, as shown in FIG. 7A, the CNTs 23c are impregnated with an insulating material 23a by using ALD (atomic layer deposition), MLD (molecular layer deposition), plasma CVD, coating, or particle dispersion. Thus, the CNTs 23c are buried in the insulating material 23a. The insulating material 23a is formed to the extent that the CNTs 23c are covered with the insulating material 23a. Thus, a CNT-containing layer 23 dispersed with a plurality of CNTs 23c is formed in the insulating material 23a. Here, CMP (chemical mechanical polishing) may be performed as necessary on the upper surface side of the CNT-containing layer 23.

Next, as shown in FIG. 7B, a low resistance carbon film is formed on the CNT-containing layer 23. The film formation of the low resistance carbon film 28 is performed under a condition similar to that for the low resistance carbon film 27, for instance. Subsequently, on the low resistance carbon film 28, a metal film 25 and a stopper interconnect film 26 are formed by sputtering or CVD.

Next, by selective etching, the stacked body 80a shown in FIG. 7B is periodically divided into memory cells 80 (not shown). Then, the insulating material 23a is removed from the side surface of the CNT-containing layer 23 using e.g. a dilute hydrofluoric acid solution to provide a gap 23g between the low resistance carbon film 27 and the low resistance carbon film 28. Thus, the memory cell 80 shown in FIG. 2B is formed. If the insulating material 23a is not removed, the memory cell 80 shown in FIG. 2C is formed. An element isolation layer 40 is formed between the memory cells 80.

### Second Embodiment

Next, a variation with the aforementioned memory cell 80 partially modified is described. In the following description, the same components as those of the aforementioned memory cell 80 are labeled with like reference numerals, and the description thereof is omitted as appropriate.

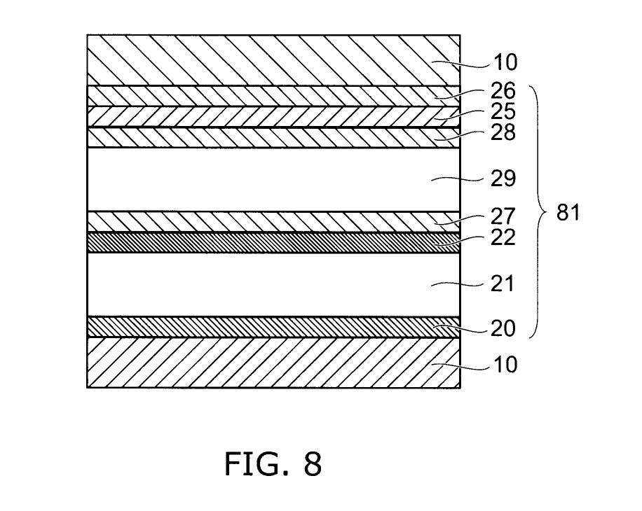

FIG. 8 is a schematic view of the main part of a memory cell section of a nonvolatile memory device according to a second embodiment. FIG. 8 shows a cross section of the main part of a memory cell 81.

In the memory cell 81, the aforementioned CNT-containing layer 23 is replaced by a high resistance carbon film 29 (first amorphous carbon layer). The high resistance carbon film 29 functions as a memory layer. The material of the high resistance carbon film 29 is e.g. amorphous carbon. The memory layer based on the high resistance carbon film 29 achieves faster switching operation than the memory layer primarily composed of oxide film (e.g., manganese oxide). Except the high resistance carbon film 29, the memory cell 81 is formed by a manufacturing process similar to that for the memory cell 80.

The high resistance carbon film 29 is formed by plasma CVD. For instance, the high resistance carbon film 29 is formed by using one of the following techniques.

(1) Forming the film by setting the film formation temperature lower than that for the low resistance carbon film 27, 28 (second amorphous carbon layer).

(2) Using C₂H₂ (acetylene)/He as a raw material gas, which has higher C/H ratio than C₃H₆ (propylene)/He.

(3) Using electrical discharge power lower than that in forming the low resistance carbon film 27, 28.

(4) Using film formation pressure lower than that in forming the low resistance carbon film 27, 28.

(5) Using electrical discharge frequency lower than that in forming the low resistance carbon film 27, 28.

These techniques may be suitably combined. Furthermore, the high resistance carbon film 29 may be formed by ion beam deposition.

The high resistance carbon film 29 thus formed contains less hydrogen (H) than the low resistance carbon film 27, 28. Furthermore, the density of unsaturated bonds included in the low resistance carbon film 27, 28 is higher than the density of unsaturated bonds included in the high resistance carbon film 29. For instance, the low resistance carbon film 27, 28 includes more sp² bonds and fewer sp³ bonds than the high resistance carbon film 29. Thus, the electrical resistivity of the high resistance carbon film 29 is higher than the electrical resistivity of the low resistance carbon film 27, 28. Furthermore, the density of the high resistance carbon film 29 is lower than the density of the low resistance carbon film 27, 28. The low resistance carbon film 27, 28 functions as a barrier layer between the high resistance carbon film 29 and the metal film 22, 25.

Specifically, the electrical resistivity of the low resistance carbon film 27, 28 is approximately 0.1 to 50 Ω·cm. The electrical resistivity of the high resistance carbon film 29 is approximately 1 to 200 Ω·cm. The electrical resistivity of the high resistance carbon film 29 may be higher than 200 Ω·cm. In the foregoing ranges of electrical resistivity, the electrical resistivity of the low resistance carbon film 27, 28 is set lower than the electrical resistivity of the high resistance carbon film 29. For instance, a difference of one order of magnitude or more is provided between the electrical resistivity of the low resistance carbon film 27, 28 and the electrical resistivity of the high resistance carbon film 29.

For instance, variation of the sheet resistance of the amorphous carbon film (noncrystalline carbon film) under the aforementioned film formation condition (1) is described with reference to Raman spectra.

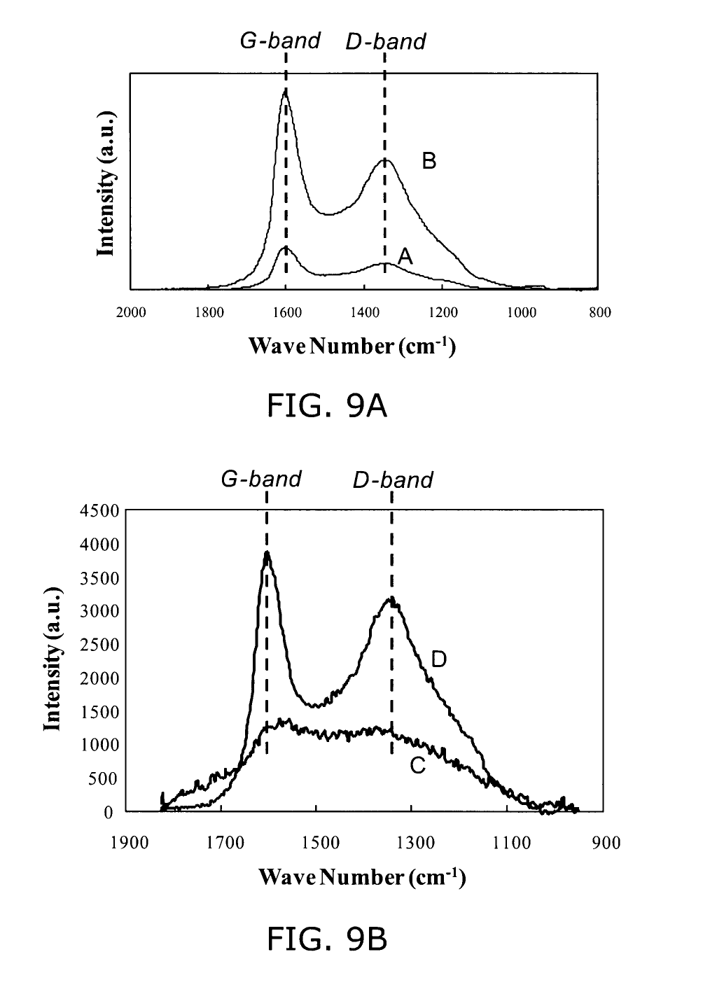

FIGS. 9A and 9B illustrate Raman spectra of carbon films. Here, FIG. 9A shows the film formation temperature dependence, and FIG. 9B shows the annealing dependence. The film thickness of the carbon film is 100 nm. The horizontal axis represents wave number (cm⁻¹), and the vertical axis represents intensity (arbitrary unit (a.u.)).

In FIG. 9A, line A is the spectrum of the high resistance carbon film (sheet resistance 142.5 Ω·cm), and line B is the spectrum of the low resistance carbon film (sheet resistance 34.0 Ω·cm). The film formation temperature of the high resistance carbon film indicated by line A is lower than the film formation temperature of the low resistance film indicated by line B.

Line B prominently shows the in-plane vibration mode due to the graphite component (G-band (1580 cm⁻¹)) and the mode due to the disorder of the graphite structure (D-band (1360 cm⁻¹)). That is, the low resistance carbon film indicated by line B is made of not a complete graphite crystal, but an amorphous material including a certain amount of graphite component.

In contrast, the intensity of the in-plane vibration mode of the high resistance carbon film indicated by line A is lower than the intensity of the in-plane vibration mode of the low resistance carbon film indicated by line B. Hence, it can be determined that less graphite component is contained in the high resistance carbon film indicated by line A than in the low resistance carbon film indicated by line B. Furthermore, the D-band is observed in the high resistance carbon film indicated by line A. Hence, the high resistance carbon film indicated by line A is also amorphous.

Thus, by varying the film formation temperature, the content of graphite component included in the amorphous carbon film can be varied to control the sheet resistance of the amorphous carbon film.

On the other hand, line C of FIG. 9B is the spectrum of the carbon film immediately after film formation. Line D is the spectrum of the carbon film obtained by annealing the carbon film of line C at 700° C. for one minute.

As seen from FIG. 9B, the in-plane vibration mode is enhanced by annealing. That is, the graphite component in the carbon film can be increased by annealing. Hence, the content of the graphite component can be controlled also by annealing. Consequently, the sheet resistance of the amorphous carbon film can be controlled.

Next, the operation of the memory cell 81 is described.

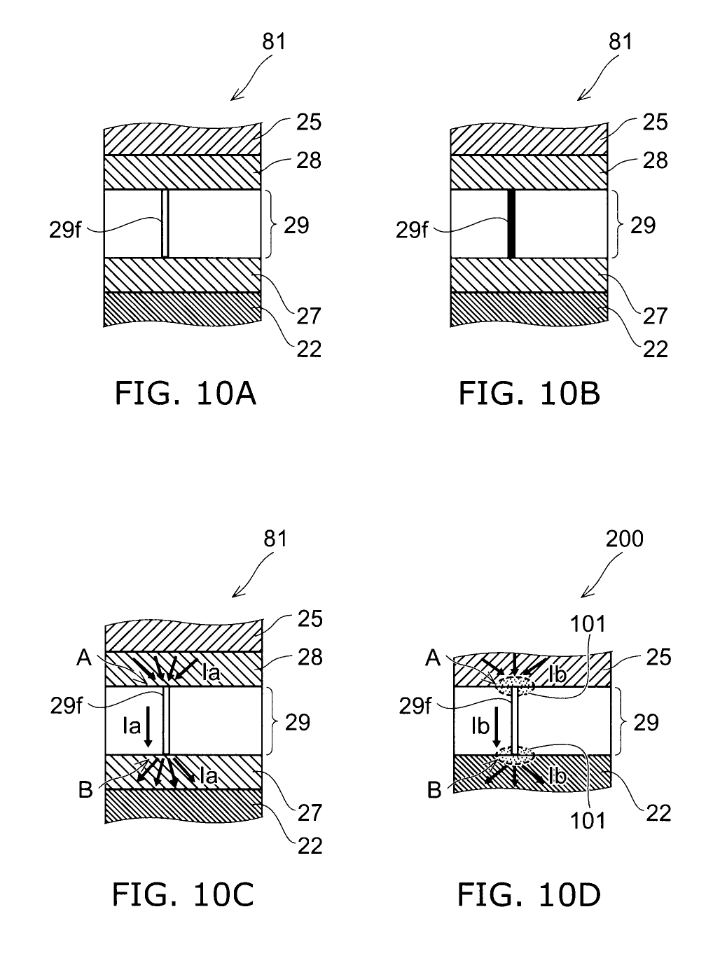

FIGS. 10A to 10D illustrate the main part of the operation of the memory cell according to the second embodiment.

First, the forming operation of the memory cell 81 is performed. A prescribed voltage is applied between the lower interconnect 10 and the upper interconnect 11. Then, a low resistance filament 29f is selectively formed in the high resistance carbon film 29. This state is shown in FIG. 10A. In FIG. 10A, as an example, one filament 29f is illustrated. However, the number of filaments is not limited thereto.

At this stage, a low resistance filament 29f is formed in the high resistance carbon film 29. This means that, for instance, information “1” is written to the memory cell 81. Next, a prescribed voltage is applied between the lower interconnect 10 and the upper interconnect 11 to perform the reset operation of the memory cell 81. By this reset operation, the filament 29f changes from the low resistance state to the high resistance state “0”. That is, the information “1” in the memory cell 81 turns to information “0”. This means that the information is erased from the memory cell 81. This state is shown in FIG. 10B. Next, the set operation is performed on the memory cell 81. Then, the filament 29f changes again from the high resistance state “0” to the low resistance state “1”.

Thus, the filament 29f changes from the high resistance state “0” to the low resistance state “1” by the set operation, and changes from the low resistance state “1” to the high resistance state “0” by the reset operation. One of the possible reasons for such state change of the filament 29f is that the bonding state in the filament 29f reversibly transitions between a first state and a second state. Here, the first state is the state in which the carbon-carbon bond is unsaturated (e.g., sp² bond). The second state is the state in which the carbon-carbon bond is saturated (e.g., sp³ bond). Thus, in the memory cell 81, the filament 29f formed in the high resistance carbon film 29 contributes to memory switching (programming and erasure of information).

Here, the width of the filament 29f is narrower than the width of the memory cell 81. The current flows through this ultrafine filament 29f. Hence, the current flowing in the filament 29f has high current density. Consequently, in the memory cell 81, as shown in FIG. 10C, the high density current Ia concentrates on the sites A, B. This locally generates heat at the sites A, B. However, the high resistance carbon film 29 and the low resistance carbon film 27, 28 are both primarily composed of carbon. Hence, local heat generation at the sites A, B is less likely to cause interdiffusion of components between the low resistance carbon film 27, 28 and the high resistance carbon film 29. Likewise, chemical reaction is less likely to occur between the low resistance carbon film 27, 28 and the high resistance carbon film 29.

Furthermore, the low resistance carbon film 27, 28 has higher density than the high resistance carbon film 29. Hence, the low resistance carbon film 27, 28 functions as a barrier film provided between the high resistance carbon film 29 and the metal film 22, 25. Furthermore, the low resistance carbon film 27, 28 has higher adhesiveness to the metal film 22, 25 than the high resistance carbon film 29. The adhesiveness between the high resistance carbon film 29 and the low resistance carbon film 27, 28 is high, because they are both primarily composed of carbon. Hence, in the memory cell 81, peeling is less likely to occur at the interface of the high resistance carbon film 29 and the low resistance carbon film 27, 28, and the interface of the low resistance carbon film 27, 28, and the metal film 22, 25.

Furthermore, the current Ia diffuses in the low resistance carbon film 27, 28 having low electrical resistivity, and then further diffuses in the metal film 22, 25. Hence, concentration of the current Ia is less likely to occur at the interface of the metal film 22 and the low resistance carbon film 27, and the interface of the metal film 25 and the low resistance carbon film 28. Thus, interdiffusion of components and chemical reaction are less likely to occur at the interface of the metal film 22 and the low resistance carbon film 27, and the interface of the metal film 25 and the low resistance carbon film 28. Hence, denoting the set voltage by Vs and the reset voltage by Vres, as illustrated in FIG. 3D, Vs and Vres are stable even if the number of reprograms increases.

In contrast, FIG. 10D shows a memory cell 200 not including the low resistance carbon film 27, 28. In the memory cell 200, the metal film 22, 25 is in direct contact with the high resistance carbon film 29. Here, if a high density current Ib flows in the filament 29f, the current Ib concentrates on the sites A, B. As described above, the current Ib is higher than the current Ia. This further increases the local heat generation at the sites A, B, and makes interdiffusion of components and chemical reaction more likely to occur at the interface of the metal film 22, 25 and the high resistance carbon film 29.

For instance, with the increase of the number of reprograms on the memory cell 200, the aforementioned carbide layer 101, for instance, occurs at the interface of the metal film 22, 25 and the high resistance carbon film 29. The carbide layer 101 grows with the increase of the number of reprograms, and may erode the high resistance carbon film 29. Thus, the thickness of the high resistance carbon film 29 may be thinned with the increase of the number of reprograms. Furthermore, if the metal component of the metal film 22, 25 diffuses into the high resistance carbon film 29, the high resistance carbon film 29 may take on metallic nature.

Hence, in the memory cell 200, denoting the set voltage by Vs and the reset voltage by Vres, as illustrated in FIG. 4B, Vs and Vres decrease with the increase of the number of reprograms. Thus, in the memory cell 200, Vs and Vres are unstable.

Vs and Vres decrease with the increase of the number of reprograms and asymptotically approach 0 V. Then, the difference between Vs and Vres is reduced. Thus, the discrimination between Vs and Vres is made difficult, and malfunctions are made more likely to occur in the program operation and the read operation. To avoid this, the high resistance carbon film 29 may be formed with a larger thickness so that a certain thickness remains even after the thickness erosion of the high resistance carbon film 29. However, with the increase of the thickness of the high resistance carbon film 29, the height of the memory cell increases. This decreases the mechanical strength of the memory cell.

In contrast, the high resistance carbon film 29 in the memory cell 81 is less prone to erosion, because of the presence of the low resistance carbon film 27, 28.

Furthermore, the metal component of the metal film 22, 25 is less likely to diffuse into the high resistance carbon film 29. Thus, the memory cell 81 has higher reliability. Furthermore, as a memory layer, the memory cell 81 uses not an oxide film but a high resistance carbon film 29. This enables faster program operation and read operation. In the second embodiment, the configuration including the low resistance carbon films 27, 28 has been illustrated. However, one of the low resistance carbon films 27, 28 may be omitted as necessary.

The embodiments have been described above with reference to examples. However, the embodiments are not limited to these examples. That is, these examples can be suitably modified by those skilled in the art, and such modifications are also encompassed within the scope of the embodiments as long as they include the features of the embodiments. For instance, various components of the above examples and their layout, material, condition, shape, size and the like are not limited to those illustrated, but can be suitably modified.

For instance, the nonvolatile memory device of the embodiments is not limited to the so-called cross-point type in which a memory cell is connected at the crossing position of two interconnects. In addition, for instance, the so-called probe memory in which a probe is brought into contact with each of a plurality of memory cells to perform programming and reading, and the memory of the type in which a memory cell is selected by a transistor or other switching element to perform programming and reading, are also encompassed within the scope of the embodiments.

Furthermore, various components of the above embodiments can be combined with each other as long as technically feasible, and such combinations are also encompassed within the scope of the embodiments as long as they include the features of the embodiments.

Furthermore, those skilled in the art can conceive various modifications and variations within the spirit of the embodiments, and it is understood that such modifications and variations are also encompassed within the scope of the embodiments. For instance, the configuration in which the diode layer is omitted as necessary from the memory cell is also encompassed in the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a memory cell connected to a first interconnect and a second interconnect,
the memory cell including a plurality of layers,
the plurality of layers including:
a carbon-containing memory layer sandwiched between a first electrode film and a second electrode film; and
a carbon-containing barrier layer provided at least one of between the first electrode film and the memory layer and between the second electrode film and the memory layer, and
the barrier layer having lower electrical resistivity than the memory layer.

2. The device according to claim 1, wherein the memory layer is a layer containing a plurality of carbon nanotubes.

3. The device according to claim 2, wherein the memory layer is a layer in which the carbon nanotubes are disposed in a gap formed between the barrier layers provided between the first electrode film and the memory layer and between the second electrode film and the memory layer.

4. The device according to claim 2, wherein the memory layer is a layer in which the plurality of carbon nanotubes are dispersed in an insulating material.

5. The device according to claim 2, wherein each of the carbon nanotubes is a single-wall nanotube made of a single layer.

6. The device according to claim 2, wherein each of the carbon nanotubes is a multi-wall nanotube made of multiple layers.

7. The device according to claim 2, wherein one end of at least one of the carbon nanotubes in the memory layer is in contact with a first barrier layer provided between the first electrode film and the memory layer, and one other end of the carbon nanotube is in contact with a second barrier layer provided between the second electrode film and the memory layer.

8. The device according to claim 1, wherein the memory layer is a first amorphous carbon layer.

9. The device according to claim 1, wherein the barrier layer is a second amorphous carbon layer.

10. The device according to claim 1, wherein density of unsaturated bonds included in the barrier layer is higher than density of unsaturated bonds included in the memory layer.

11. The device according to claim 1, wherein the memory layer has lower hydrogen content than the barrier layer.

12. The device according to claim 9, wherein the second amorphous carbon layer has higher density than the first amorphous carbon layer.

13. The device according to claim 1, wherein the electrical resistivity of the barrier layer is 0.1 to 50 Ω·cm.

14. The device according to claim 1, wherein the electrical resistivity of the memory layer is approximately 1 to 200 Ω·cm.

15. The device according to claim 1, wherein the first interconnect crosses the second interconnect.
